(19) United States
(12) Patent Application Publication
(10) Pub. No.: US 2019/0363728 A1
(43) Pub. Date: Nov. 28, 2019

(54) Digital to Analog Converter Circuit and Operating Method Thereof

(71) Applicant: Raydium Semiconductor Corporation, Hsinchu (TW)

(72) Inventors: WAI-CHU WANG, Hsinchu (TW); CHIH-CHUAN HUANG, Zhubei City (TW)

(21) Appl. No.: 16/358,974

(22) Filed: Mar. 20, 2019

(30) Foreign Application Priority Data
May 22, 2018 (TW) 107117398

(51) Int. Cl. H03M 1/66; G09G 3/36

(52) U.S. Cl. CPC H03M 1/66; G09G 3/3674

(57) ABSTRACT

A digital to analog converter circuit applied to a source driving apparatus is disclosed. The digital to analog converter circuit includes P-type transistors coupled in series, N-type transistors coupled in series and a substrate voltage control unit. The substrate voltage control unit is coupled to substrates of the P-type transistors and substrates of the N-type transistors respectively and used for controlling the substrates of the P-type transistors to have a first substrate voltage and controlling the substrates of the N-type transistors to have a second substrate voltage. The first substrate voltage is an operating voltage substituted by a specific voltage difference and the second substrate voltage is a ground voltage added by the specific voltage difference, and the operating voltage is higher than the ground voltage.

### BACKGROUND OF THE INVENTION

### 1. Field of the Invention

The invention relates to a display; in particular, to a digital to analog converter circuit and operating method thereof applied to a display driving integrated circuit.

### 2. Description of the Prior Art

Due to the increasing popularity of liquid crystal display panels of high resolution (e.g., 4K or 8K), there is also a problem that the specification requirements are becoming more and more strict in the panel manufacturing technology.

Generally, as shown in FIG. 1A and FIG. 1B, a common digital to analog converter circuit is to connect substrates of P-type transistors MP0˜MP7 coupled in series with an operating voltage AVDD or connect substrates of N-type transistors MN0 to MN7 coupled in series with a ground voltage AGND.

However, as shown in FIG. 2, different voltage levels VGM10˜VGM18 are provided by a voltage-dividing resistor string RS and the digital analog converters DAC0˜DAC255 as switches provide an input signal SIN to the channel operational amplifier OP at the back end. When the digital to analog converters DAC0˜DAC255 transmit different voltage levels, the voltage between the source electrode and the substrate of the transistor will be larger than 0, and the substrate and source electrode of the transistor will be reversed, resulting in the increasing of the threshold voltage and the substrate effect will be generated, which in turn affects the on-resistance (Ron) of the transistor and causes the reaction speed of the digital to analog converters DAC0˜DAC255 to be slow, and the charging time for the channel operational amplifier OP providing the output signal SOUT to charge the liquid crystal panel is affected by the input signal SIN.

Since the common digital analog converter circuit is to connect the substrates of the P-type transistors and the N-type transistors to the operating voltage AVDD and the ground voltage AGND respectively, as shown in FIG. 3, the voltage levels (e.g., VGM2, VGM1, VGM17, VGM18) transmitted by the transistors corresponding to large codes (e.g., FEH, FFH) will be closer to the operating voltage AVDD or the ground voltage AGND; on the contrary, the voltage levels (e.g., VGM9, VGM8, VGM10, VGM11) transmitted by the transistors corresponding to small codes (e.g., 00H, 01H) will be closer to the half-voltage level AHVDD, resulting in a larger voltage between the source electrode and the substrate of the transistor and the substrate effect will become serious.

### SUMMARY OF THE INVENTION

Therefore, the invention provides a digital to analog converter circuit and operating method thereof to solve the above-mentioned problems of the prior arts.

A preferred embodiment of the invention is a digital to analog converter circuit. In this embodiment, the digital to analog converter circuit is applied to a source driving apparatus. The digital to analog converter circuit includes P-type transistors coupled in series, N-type transistors coupled in series and a substrate voltage control unit. The substrate voltage control unit is coupled to substrates of the P-type transistors and substrates of the N-type transistors respectively and used for controlling the substrates of the P-type transistors to have a first substrate voltage and controlling the substrates of the N-type transistors to have a second substrate voltage. The first substrate voltage is an operating voltage substituted by a specific voltage difference and the second substrate voltage is a ground voltage added by the specific voltage difference, and the operating voltage is higher than the ground voltage.

In an embodiment, the substrate voltage control unit determines the specific voltage difference according to component characteristics of the P-type transistors and the N-type transistors, so as to reduce starting resistances and threshold voltages of the P-type transistors and the N-type transistors and avoid forward conduction.

In an embodiment, when source electrodes of the P-type transistors receive a first input data signal and have a first source voltage, a voltage difference between the first source voltage of the P-type transistors and the first substrate voltage is smaller than a voltage difference between the first source voltage and the operating voltage.

In an embodiment, when the first input data signal has a voltage approaching one half of the operating voltage, the first source voltage approaches one half of the operating voltage.

In an embodiment, when the first input data signal has a voltage approaching the operating voltage, the first source voltage approaches the operating voltage and the specific voltage difference approaches zero.

In an embodiment, when source electrodes of the N-type transistors receive a second input data signal and have a second source voltage, a voltage difference between the second source voltage of the N-type transistors and the second substrate voltage is smaller than a voltage difference between the second source voltage and the ground voltage.

In an embodiment, when the second input data signal has a voltage approaching one half of the operating voltage, the second source voltage approaches one half of the operating voltage.

In an embodiment, when the second input data signal has a voltage approaching the ground voltage, the second source voltage approaches the ground voltage and the specific voltage difference approaches zero.

In an embodiment, the source driving apparatus further comprises an operational amplifier having a first input terminal, a second input terminal and an output terminal, and the first input terminal and the output terminal of the operational amplifier are coupled.

In an embodiment, one terminal of the P-type transistors coupled in series is coupled to the second input terminal of the operational amplifier.

In an embodiment, the source driving apparatus further comprises a voltage-dividing resistor string and the voltage-dividing resistor string comprises voltage-dividing resistors coupled in series, another terminal of the P-type transistors coupled in series is coupled to one terminal of the voltage-dividing resistor string or coupled between any two adjacent voltage-dividing resistors to receive a first input data signal.

In an embodiment, one terminal of the N-type transistors coupled in series is coupled to the first input terminal of the operational amplifier.

In an embodiment, the source driving apparatus further comprises a voltage-dividing resistor string and the voltage-dividing resistor string comprises voltage-dividing resistors coupled in series, another terminal of the N-type transistors coupled in series is coupled to one terminal of the voltage-dividing resistor string or coupled between any two adjacent voltage-dividing resistors to receive a second input data signal.

Another preferred embodiment of the invention is a digital to analog converter circuit operating method. In this embodiment, the digital to analog converter circuit operating method is used for operating a digital to analog converter circuit in a source driving apparatus. The digital to analog converter circuit includes P-type transistors, N-type transistors and a substrate voltage control unit. The P-type transistors is coupled in series and the N-type transistors is coupled in series. The substrate voltage control unit is coupled to substrates of the P-type transistors and substrates of the N-type transistors respectively. The digital to analog converter circuit operating method includes steps of: (a) determining a specific voltage difference; (b) substituting an operating voltage by the specific voltage difference to obtain a first substrate voltage and controlling the substrates of the P-type transistors to have the first substrate voltage; and (c) adding a ground voltage to the specific voltage difference to obtain a second substrate voltage and controlling the substrates of the N-type transistors to have the second substrate voltage, wherein the operating voltage is higher than the ground voltage.

Compared to the prior art, the digital to analog converter circuit and the operation method thereof can reduce the substrate effect of the conventional transistors by changing the substrate voltage level according to the component characteristics of the transistors, so that the starting resistance and the threshold voltage of the transistor can be reduced and the forward conduction can be avoided, so as to speed up the reaction speed of the digital to analog converter circuit, and the charging time of the channel operational amplifier providing the output signal to the liquid crystal panel is not affected, which is beneficial to the design of the back-end channel operational amplifier circuit.

The advantage and spirit of the invention may be understood by the following detailed descriptions together with the appended drawings.

### BRIEF DESCRIPTION OF THE APPENDED DRAWINGS

FIG. 1A illustrates a schematic diagram of connecting a substrate of P-type transistors coupled in series with an operating voltage in a digital to analog converter circuit of the prior art.

FIG. 1B illustrates a schematic diagram of connecting a substrate of N-type transistors coupled in series with a ground voltage in a digital to analog converter circuit of the prior art.

FIG. 2 illustrates a schematic diagram showing that when the voltage-dividing resistor string provides different voltage levels and transmitted through the digital to analog converter circuit, the source electrode and the substrate of the transistor in the digital to analog converter circuit is reversely biased, resulting in the substrate effect due to the increasing of the threshold voltage.

FIG. 3 illustrates a schematic diagram showing that the voltage level transmitted by the transistor corresponding to smaller code approaches the half voltage level, resulting in a larger voltage between the source electrode and the substrate of the transistor, resulting in a more significant substrate effect.

FIG. 4A illustrates a schematic diagram showing that a digital to analog converter of a digital to analog converter circuit includes P-type transistors in an embodiment of the invention.

FIG. 4B illustrates a schematic diagram showing that a digital to analog converter of a digital to analog converter circuit includes N-type transistors in an embodiment of the invention.

FIG. 5A and FIG. 5B illustrate schematic diagrams showing that the on-resistance and the threshold voltage of the transistor versus the drain-source voltage of the transistor in the invention and the prior art respectively.

FIG. 6 illustrates a flowchart of the digital to analog converter circuit operating method in another preferred embodiment of the invention.

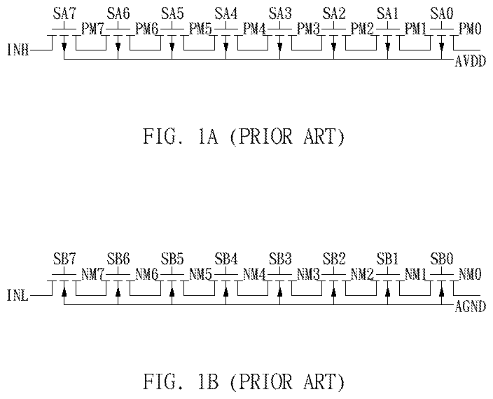

### DETAILED DESCRIPTION OF THE INVENTION

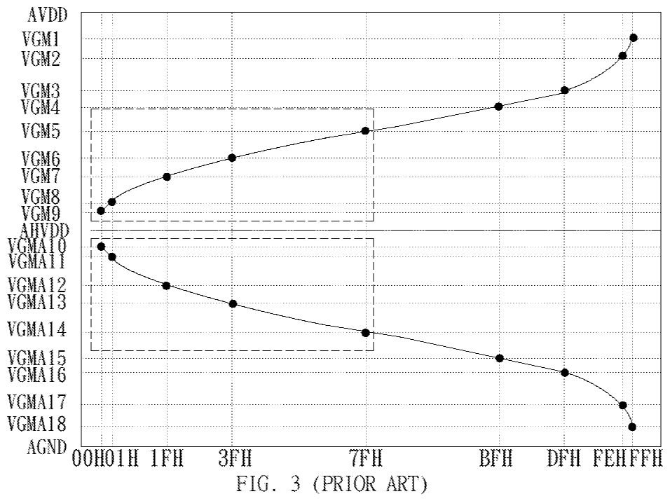

A preferred embodiment of the invention is a digital to analog converter circuit. In this embodiment, the digital to analog converter is applied to a source driving apparatus in the display, and the digital to analog converter circuit can include digital to analog converters as shown in FIG. 3. The digital to analog converters can be formed by P-type transistors coupled in series with each other or by N-type transistors coupled in series with each other. The substrates of the P-type transistors and the substrates of the N-type transistors are coupled to the first substrate voltage and the second substrate voltage respectively, wherein the first substrate voltage is higher than the second substrate voltage.

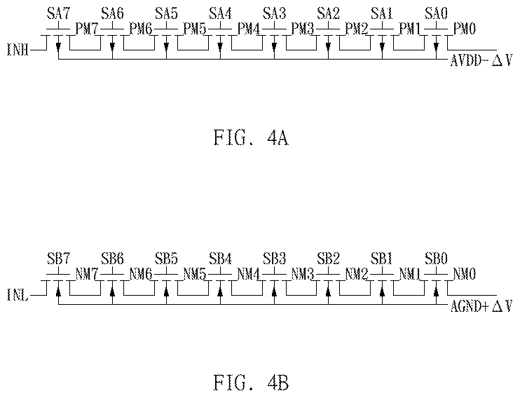

As shown in FIG. 4A, the digital to analog converter in the digital to analog converter circuit can include P-type transistors PM0˜PM7. The P-type transistors PM0˜PM7 are sequentially coupled in series and the gates of the P-type transistors PM0˜PM7 receive the control signals SA0˜SA7 respectively. The substrates of the P-type transistors PM0˜PM7 can be coupled to the first substrate voltage (AVDD−ΔV) and the first substrate voltage (AVDD−ΔV) can be provided by the substrate voltage control unit (not shown in the figures), but not limited to this. The first substrate voltage (AVDD−ΔV) can be the operating voltage AVDD minus a specific voltage difference ΔV. For example, the specific voltage difference ΔV can be 2 volts, but not limited to this.

In practical applications, the magnitude of the first substrate voltage (AVDD−ΔV) can be determined according to the component characteristics of the P-type transistors PM0-PM7, as long as the starting resistance and the threshold voltage of the transistors can be reduced and the forward conduction can be avoided, which can be adjusted according to actual needs.

If the source electrodes of the P-type transistors PM0˜PM7 receive the first input data signal INH and have the first source voltage, the voltage difference between the first source voltage of the P-type transistors PM0˜PM7 and the first substrate voltage (AVDD−ΔV) can be smaller than the voltage difference between the first source voltage and the operating voltage (AVDD). That is to say, since the substrate voltage of the P-type transistors PM0˜PM7 is reduced from the conventional operating voltage AVDD to the first substrate voltage (AVDD−ΔV), the voltage between the source electrodes of the P-type transistors PM0˜PM7 and the substrate becomes small, so that the substrate effect can be effectively reduced.

When the first input data signal INH has a voltage approaching one-half of the operating voltage AVDD (e.g., the half voltage level AHVDD), the first source voltage approaches one half of the operating voltage AVDD (e.g., the half voltage level AHVDD). When the first input data signal INH has a voltage approaching the operating voltage AVDD, the first source voltage approaches the operating voltage AVDD and the specific voltage difference ΔV approaches zero.

As shown in FIG. 4B, the digital to analog converter in the digital to analog converter circuit can include N-type transistors NM0˜NM7. The N-type transistors NM0˜NM7 are sequentially coupled in series with each other, and the gates of the N-type transistors NM0˜NM7 receive control signals SB0˜SB7 respectively. The substrates of the N-type transistors NM0˜NM7 can be coupled to the second substrate voltage (AGND+ΔV), and the second substrate voltage (AGND+ΔV) can be provided by the substrate voltage control unit (not shown in the figures), but not limited to this. The second substrate voltage (AGND+ΔV) can be a ground voltage AGND plus a specific voltage difference ΔV. For example, the specific voltage difference ΔV can be 2 volts, but not limited to this.

In practical applications, the magnitude of the second substrate voltage (AGND+ΔV) can be determined according to the component characteristics of the N-type transistors NM0˜NM7, as long as the starting resistance and the threshold voltage of the transistors can be reduced and the forward conduction can be avoided, which can be adjusted according to actual needs.

If the source electrodes of the N-type transistors NM0˜NM7 receive the second input data signal INL and have the second source voltage, the voltage difference between the second source voltage of the N-type transistors NM0˜NM7 and the second substrate voltage (AGND+ΔV) is smaller than the voltage difference between the second source voltage and the ground voltage AGND. That is to say, since the substrate voltage of the N-type transistors NM0˜NM7 is raised from the conventional ground voltage AGND to the second substrate voltage (AGND+ΔV), the voltage between the source electrodes of the N-type transistors NM0˜NM7 and the substrate becomes small, so that the substrate effect can be effectively reduced.

When the second input data signal INL has a voltage approaching one half of the operating voltage AVDD (e.g., the half voltage level AHVDD), the second source voltage approaches one half of the operating voltage AVDD (e.g., the half voltage level AHVDD). When the second input data signal INL has a voltage approaching the ground voltage AGND, the second source voltage approaches the ground voltage AGND and the specific voltage difference ΔV approaches zero.

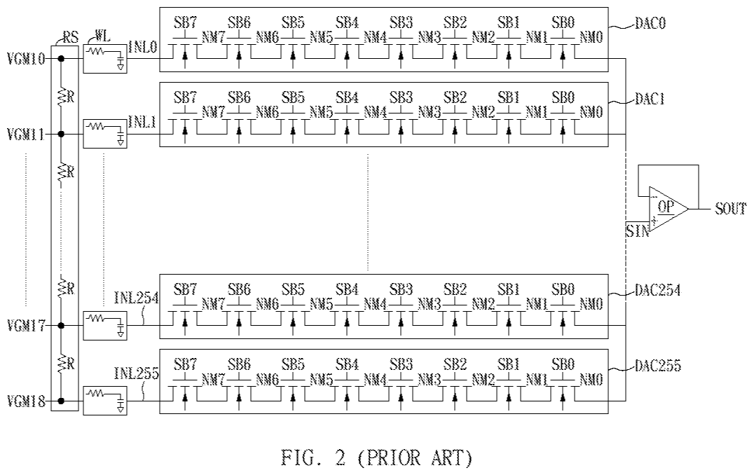

In practical applications, one terminal of the P-type transistors PM0˜PM7 coupled in series in FIG. 4A can be coupled to the second input terminal +of the operational amplifier OP as shown in FIG. 2, and the first input terminal ˜and the output terminal of the operational amplifier OP are coupled. Another terminal of the P-type transistors PM0˜PM7 is coupled to one terminal of the voltage dividing resistor string RS or between any two adjacent dividing resistors R as in FIG. 2 to receive the first input data signal INH.

Similarly, one terminal of the N-type transistors NM0˜NM7 coupled in series in FIG. 4B can be coupled to the second input terminal + of the operational amplifier OP as shown in FIG. 2, and the first input terminal − and the output terminal of the operational amplifier OP are coupled. Another terminal of the N-type transistors NM0˜NM7 is coupled to one terminal of the voltage dividing resistor string RS or between any two adjacent dividing resistors R as in FIG. 2 to receive the second input data signal INL.

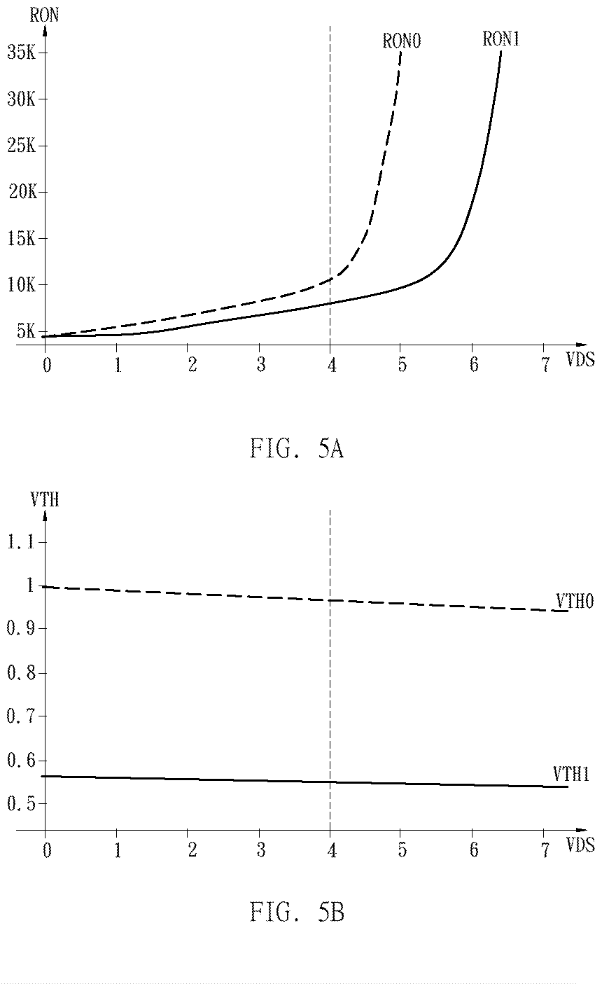

Then, please refer to FIG. 5A and FIG. 5B. FIG. 5A and FIG. 5B show a diagram of comparing the on-resistance RON and the threshold voltage VTH of the transistors with the drain-source voltage VDS in the invention and the prior art.

As shown in FIG. 5A, the on-resistance curves of the transistors in the invention and the prior art are RON1 and RON0 respectively. If the drain-source voltage VDS is equal to 4 volts, it can be clearly found that the on-resistance curve RON1 of the transistor in the invention is lower than the on-resistance curve RON0 of the transistor in the prior art.

As shown in FIG. 5B, the threshold voltage curves of the transistor in the invention and the prior art are VTH1 and VTH0 respectively. If the drain-source voltage VDS is equal to 4 volts, it can be clearly found that the threshold voltage curve VTH1 of the transistor in the invention is lower than the threshold voltage curve VTH0 of the transistor in the prior art.

According to FIG. 5A and FIG. 5B, since the substrate voltage of the P-type transistors in the digital to analog converter circuit of the invention is reduced from the conventional operating voltage AVDD to the first substrate voltage (AVDD−ΔV) and the substrate voltage of the N-type transistors is raised from the conventional ground voltage AGND to the second substrate voltage (AGND+ΔV), the voltage between the source electrodes and the substrates of the P-type transistors and the N-type transistors will become smaller, so that the substrate effect can be effectively reduced, and the effects of reducing the starting resistance and the threshold voltage of the transistor and avoiding the forward conduction can be achieved.

Another preferred embodiment of the invention is a digital to analog converter circuit operating method. In this embodiment, the digital to analog converter circuit operating method is used to operate a digital to analog converter circuit in the source driver. The digital to analog converter circuit includes P-type transistors, N-type transistors and a substrate voltage control unit. The P-type transistors are coupled in series with each other and the N-type transistors are coupled in series with each other. The substrate voltage control unit is coupled to the substrates of the P-type transistors and the substrates of the N-type transistors.

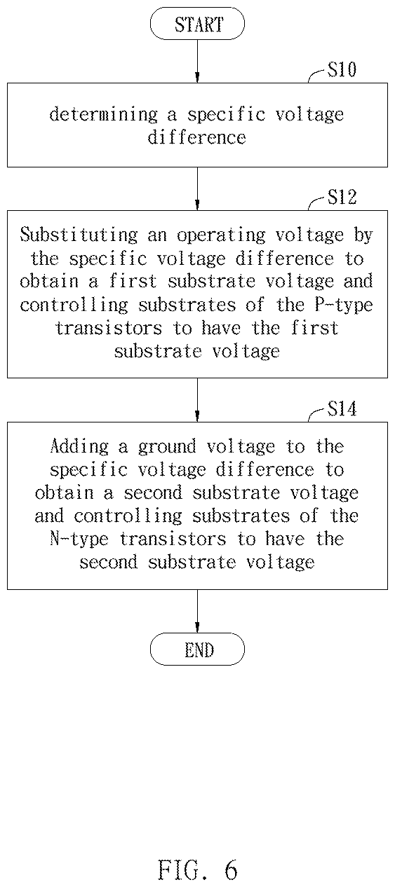

Please refer to FIG. 6. FIG. 6 illustrates a flowchart of the digital to analog converter circuit operating method in this embodiment. As shown in FIG. 6, the digital to analog converter circuit operating method can include the following steps.

Step S10: determining a specific voltage difference;

Step S12: substituting an operating voltage by the specific voltage difference to obtain a first substrate voltage and controlling substrates of the P-type transistors to have the first substrate voltage; and

Step S14: adding a ground voltage to the specific voltage difference to obtain a second substrate voltage and controlling substrates of the N-type transistors to have the second substrate voltage, wherein the operating voltage is higher than the ground voltage.

In practical applications, Step S10 determines the specific voltage difference according to component characteristics of the P-type transistors and the N-type transistors, so as to reduce the starting resistance and threshold voltage of the transistors and avoid forward conduction.

If the source electrodes of the P-type transistors receive a first input data signal and have a first source voltage, a voltage difference between the first source voltage of the P-type transistors and the first substrate voltage will be smaller than a voltage difference between the first source voltage and the operating voltage. When the first input data signal has a voltage close to one-half of the operating voltage, the first source voltage approaches one-half of the operating voltage; when the first input data signal has a voltage close to the operating voltage, the first source voltage approaches the operating voltage and the specific voltage difference approaches zero.

If the source electrodes of the N-type transistors receive a second input data signal and have a second source voltage, a voltage difference between the second source voltage of the N-type transistors and the second substrate voltage will be smaller than a voltage difference between the second source voltage and the ground voltage.

When the second input data signal has a voltage close to one-half of the operating voltage, the second source voltage approaches one half of the operating voltage; when the second input data signal has a voltage close to the ground voltage, the second source voltage approaches the ground voltage and the specific voltage difference approaches zero.

Compared to the prior art, the digital to analog converter circuit and the operation method thereof can reduce the substrate effect of the conventional transistors by changing the substrate voltage level according to the component characteristics of the transistors, so that the starting resistance and the threshold voltage of the transistor can be reduced and the forward conduction can be avoided, so as to speed up the reaction speed of the digital to analog converter circuit, and the charging time of the channel operational amplifier providing the output signal to the liquid crystal panel is not affected, which is beneficial to the design of the back-end channel operational amplifier circuit.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A digital to analog converter circuit applied to a source driving apparatus, the digital to analog converter circuit comprising:
P-type transistors coupled in series;
N-type transistors coupled in series; and
a substrate voltage control unit, coupled to substrates of the P-type transistors and substrates of the N-type transistors respectively, for controlling the substrates of the P-type transistors to have a first substrate voltage and controlling the substrates of the N-type transistors to have a second substrate voltage;
wherein the first substrate voltage is an operating voltage substituted by a specific voltage difference and the second substrate voltage is a ground voltage added by the specific voltage difference, and the operating voltage is higher than the ground voltage.

2. The digital to analog converter circuit of claim 1, wherein the substrate voltage control unit determines the specific voltage difference according to component characteristics of the P-type transistors and the N-type transistors, so as to reduce starting resistances and threshold voltages of the P-type transistors and the N-type transistors and avoid forward conduction.

3. The digital to analog converter circuit of claim 1, wherein when source electrodes of the P-type transistors receive a first input data signal and have a first source voltage, a voltage difference between the first source voltage of the P-type transistors and the first substrate voltage is smaller than a voltage difference between the first source voltage and the operating voltage.

4. The digital to analog converter circuit of claim 3, wherein when the first input data signal has a voltage approaching one half of the operating voltage, the first source voltage approaches one half of the operating voltage.

5. The digital to analog converter circuit of claim 3, wherein when the first input data signal has a voltage approaching the operating voltage, the first source voltage approaches the operating voltage and the specific voltage difference approaches zero.

6. The digital to analog converter circuit of claim 1, wherein when source electrodes of the N-type transistors receive a second input data signal and have a second source voltage, a voltage difference between the second source voltage of the N-type transistors and the second substrate voltage is smaller than a voltage difference between the second source voltage and the ground voltage.

7. The digital to analog converter circuit of claim 6, wherein when the second input data signal has a voltage approaching one half of the operating voltage, the second source voltage approaches one half of the operating voltage.

8. The digital to analog converter circuit of claim 6, wherein when the second input data signal has a voltage approaching the ground voltage, the second source voltage approaches the ground voltage and the specific voltage difference approaches zero.

9. The digital to analog converter circuit of claim 1, wherein the source driving apparatus further comprises an operational amplifier having a first input terminal, a second input terminal and an output terminal, and the first input terminal and the output terminal of the operational amplifier are coupled.

10. The digital to analog converter circuit of claim 9, wherein one terminal of the P-type transistors coupled in series is coupled to the second input terminal of the operational amplifier.

11. The digital to analog converter circuit of claim 10, wherein the source driving apparatus further comprises a voltage-dividing resistor string and the voltage-dividing resistor string comprises voltage-dividing resistors coupled in series, another terminal of the P-type transistors coupled in series is coupled to one terminal of the voltage-dividing resistor string or coupled between any two adjacent voltage-dividing resistors to receive a first input data signal.

12. The digital to analog converter circuit of claim 9, wherein one terminal of the N-type transistors coupled in series is coupled to the first input terminal of the operational amplifier.

13. The digital to analog converter circuit of claim 12, wherein the source driving apparatus further comprises a voltage-dividing resistor string and the voltage-dividing resistor string comprises voltage-dividing resistors coupled in series, another terminal of the N-type transistors coupled in series is coupled to one terminal of the voltage-dividing resistor string or coupled between any two adjacent voltage-dividing resistors to receive a second input data signal.

14. A digital to analog converter circuit operating method, for operating a digital to analog converter circuit in a source driving apparatus, the digital to analog converter circuit comprising P-type transistors, N-type transistors and a substrate voltage control unit, the P-type transistors being coupled in series and the N-type transistors being coupled in series, the substrate voltage control unit being coupled to substrates of the P-type transistors and substrates of the N-type transistors respectively, the digital to analog converter circuit operating method comprising steps of:
(a) determining a specific voltage difference;
(b) substituting an operating voltage by the specific voltage difference to obtain a first substrate voltage and controlling the substrates of the P-type transistors to have the first substrate voltage; and
(c) adding a ground voltage to the specific voltage difference to obtain a second substrate voltage and controlling the substrates of the N-type transistors to have the second substrate voltage, wherein the operating voltage is higher than the ground voltage.

15. The digital to analog converter circuit operating method of claim 14, wherein the step (a) determines the specific voltage difference according to component characteristics of the P-type transistors and the N-type transistors, so as to reduce starting resistances and threshold voltages of the P-type transistors and the N-type transistors and avoid forward conduction.

16. The digital to analog converter circuit operating method of claim 14, wherein the substrate voltage control unit determines the specific voltage difference according to component characteristics of the P-type transistors and the N-type transistors, so as to reduce starting resistances and threshold voltages of the P-type transistors and the N-type transistors and avoid forward conduction.

17. The digital to analog converter circuit operating method of claim 16, wherein the first input data signal has a voltage approaching one half of the operating voltage, the first source voltage approaches one half of the operating voltage.

18. The digital to analog converter circuit operating method of claim 16, wherein when the first input data signal has a voltage approaching the operating voltage, the first source voltage approaches the operating voltage and the specific voltage difference approaches zero.

19. The digital to analog converter circuit operating method of claim 14, wherein when source electrodes of the N-type transistors receive a second input data signal and have a second source voltage, a voltage difference between the second source voltage of the N-type transistors and the second substrate voltage is smaller than a voltage difference between the second source voltage and the ground voltage.

20. The digital to analog converter circuit operating method of claim 19, wherein when the second input data signal has a voltage approaching one half of the operating voltage, the second source voltage approaches one half of the operating voltage.

21. The digital to analog converter circuit operating method of claim 19, wherein when the second input data signal has a voltage approaching the ground voltage, the second source voltage approaches the ground voltage and the specific voltage difference approaches zero.
